(19) United States
(12) Patent Application Publication
(10) Pub. No.: US 2025/0386480 A1
(43) Pub. Date: Dec. 18, 2025

(54) INTEGRATED CIRCUIT STRUCTURE

(71) Applicant: Taiwan Semiconductor Manufacturing Company, Ltd., Hsinchu (TW)

(72) Inventor: Jhon-Jhy LIAW, Hsinchu (TW)

(73) Assignee: Taiwan Semiconductor Manufacturing Company, Ltd., Hsinchu (TW)

(21) Appl. No.: 18/745,391

(22) Filed: Jun. 17, 2024

(51) Int. Cl. H10B 10/00; G11C 5/06

(52) U.S. Cl. CPC H10B 10/125; G11C 5/063

(57) ABSTRACT

An integrated circuit structure is provided. The integrated circuit structure includes at least one static random-access memory (SRAM) cell. The SRAM cell includes a first active region, a second active region, a third active region, a fourth active region, a first pull-up transistor, a second pull-up transistor, a first pass-gate transistor, a second pass-gate transistor, a first pull-down transistor and a second pull-down transistor. The first active region to the fourth active region follow a first routing direction. The first pull-up transistor is formed upon the third active region. The second pull-up transistor is formed upon the third active region. The first pass-gate transistor and the first pull-down transistor are formed upon the first active region. The second pass-gate transistor and the second pull-down transistor are formed upon the second active region. Each of the SRAM cells is formed on a N-well region of a P-type substrate.

### BACKGROUND

Along with the exponential growth of the semiconductor integrated circuit (IC) industry, several generations of ICs have been produced. Each generation has smaller and more complex circuits than the previous generation.

In the IC evolution, the number of interconnected devices per chip area has generally increased while the smallest component (or line) that can be created using a fabrication process has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, multi-gate transistors have been incorporated into memory devices (including, for example, static random-access memory, or SRAM cells) to reduce chip footprint while maintaining reasonable processing margins. In addition, in nanometer (22 nm and beyond) generations, the FinFET devices have become most popular candidate for high performance and lower leakage application. This is due to additional sidewalls device width (Ion performance) as well as better short channel control (subthreshold leakage). However, the FinFET device still has a fin bottom portion out of gate control problem and therefore limited the continue shrunk capability.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a circuit diagram of a single-port static random-access memory (SRAM) cell according to one embodiment.

FIG. 2 shows an equivalent circuit diagram of the SRAM cell of FIG. 1.

FIG. 3 shows a circuit diagram of a single-port static random-access memory (SRAM) cell according to one embodiment.

FIG. 4 shows an equivalent circuit diagram of the SRAM cell of FIG. 3.

FIG. 5 shows a front-side diagrammatic plan view of an exemplified SRAM cell according to FIG. 1.

FIG. 6 shows a cross section view of the semiconductor structure of FIG. 5 along a cutting line C1 according to one embodiment.

FIG. 7 shows a cross section view of the semiconductor structure of FIG. 5 along a cutting line C2 according to one embodiment.

FIG. 8 shows a cross section view of the semiconductor structure of FIG. 5 along a cutting line C3 according to one embodiment.

FIG. 9 shows a cross section view of a semiconductor structure of FIG. 5 along the cutting line C2 according to another embodiment.

FIG. 10 shows a cross section view of the semiconductor structure of FIG. 5 along the cutting line C3 according to another embodiment.

FIG. 11 shows a cross section view of a semiconductor structure of FIG. 5 along the cutting line C4 according to one embodiment.

FIG. 12 shows a diagrammatic plan view of an exemplified SRAM cell according to FIG. 3.

FIG. 13 shows a cross section view of the semiconductor structure of FIG. 12 along a cutting line C5 according to one embodiment.

FIG. 14 shows a cross section view of the semiconductor structure of FIG. 12 along a cutting line C6 according to one embodiment.

FIG. 15 shows a cross section view of a semiconductor structure of FIG. 12 along the cutting line C5 according to another embodiment.

FIG. 16 shows a cross section view of the semiconductor structure of FIG. 12 along the cutting line C6 according to another embodiment.

FIG. 17 shows another diagrammatic plan view of an exemplified SRAM cell according to FIG. 1.

FIG. 18 shows an arrangement of four level metal layers FM1 to FM4 stacked in the integrated circuit structure.

FIG. 19 shows an arrangement of the SRAM cells in the integrated circuit structure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

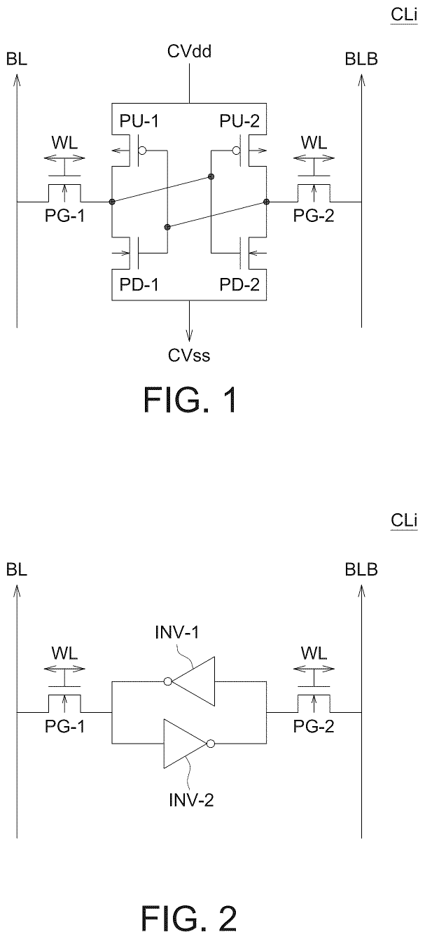

Referring to FIG. 1, FIG. 1 shows a circuit diagram of a single-port static random-access memory (SRAM) cell CLi according to one embodiment. The SRAM cell CLi includes a first pass-gate transistor PG-1, a first pull-up transistor PU-1, a first pull-down transistor PD-1, a second pass-gate transistor PG-2, a second pull-up transistor PU-2, and a second pull-down transistor PD-2.

A drain node of the first pass-gate transistor PG-1, a drain node of the first pull-up transistor PU-1, a drain node of the first pull-down transistor PD-1, a gate node of the second pull-up transistor PU-2, and a gate node of the second pull-down transistor PD-2 are electrically connected together to form a storage node.

A drain node of the second pass-gate transistor PG-2, a drain node of the second pull-up transistor PU-2, a drain node of the second pull-down transistor PD-2, a gate node of the first pull-up transistor PU-1, and a gate node of the first pull-down transistor PD-1 are electrically connected together to form another storage node.

A source node of the first pass-gate transistor PG-1 is electrically connected to a first bit line BL. A source node of the first pull-up transistor PU-1 and a source node of the second pull-up transistor PU-2 are electrically connected to a power source voltage CVdd. A source node of the first pull-down transistor PD-1 and a second pull-down transistor PD-2 are electrically connected to a common voltage CVss. A source node of the second pass-gate transistor PG-2 is electrically connected to a second bit line BLB, which is separate from the first bit line BL. A gate node of the first pass-gate transistor PG-1 and a gate node of the second pass-gate transistor PG-2 are electrically connected to a word line FM2_WL.

These transistors are formed by either FinFET transistor or vertically stacked multiple channels gate-all-around (GAA) horizontal nano-sheets transistor.

Referring to FIG. 2, FIG. 2 shows an equivalent circuit diagram of the SRAM cell CLi of FIG. 1. The first pull-up transistor PU-1 and the first pull-down transistor PD-1 of FIG. 1 form a first inverter INV-1. The second pull-up transistor PU-2 and the second pull-down transistor PD-2 of FIG. 1 form a second inverter INV-2. The first inverter INV-1 and the second inverter INV-2 are cross-coupled.

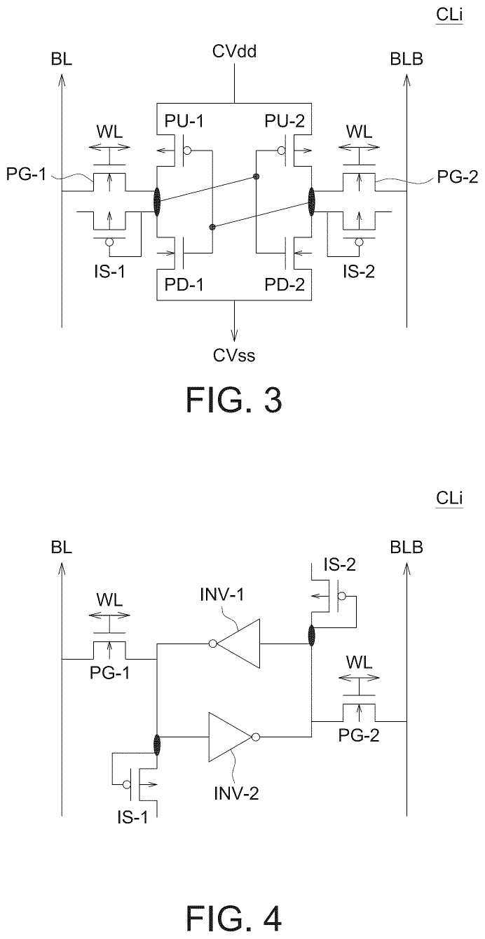

Referring to FIG. 3, FIG. 3 shows a circuit diagram of a single-port static random-access memory (SRAM) cell CLi according to one embodiment. The SRAM cell CLi includes a first pass-gate transistor PG-1, a first pull-up transistor PU-1, a first pull-down transistor PD-1, a second pass-gate transistor PG-2, a second pull-up transistor PU-2, a second pull-down transistor PD-2, a first isolation transistor IS-1 and a second isolation transistor IS-2.

A drain node of the first pass-gate transistor PG-1, a drain node of the first pull-up transistor PU-1, a drain node of the first pull-down transistor PD-1, a gate node of the second pull-up transistor PU-2, a gate node of the second pull-down transistor PD-2 and a drain node of the first isolation transistor IS-1 are electrically connected together to form a storage node. In addition, the drain node and a gate node of the first isolation transistor IS-1 are electrically connected together. A source node of the first isolation transistor IS-1 is electrically floated.

A drain node of the second pass-gate transistor PG-2, a drain node of the second pull-up transistor PU-2, a drain node of the second pull-down transistor PD-2, a gate node of the first pull-up transistor PU-1, a gate node of the first pull-down transistor PD-1 and a drain node of the second isolation transistor IS-2 are electrically connected together to form another storage node. In addition, the drain node and a gate node of the second isolation transistor IS-2 are electrically connected together. A source node of the second isolation transistor IS-2 is electrically floated.

A source node of the first pass-gate transistor PG-1 is electrically connected to a first bit line BL. A source node of the first pull-up transistor PU-1 and a source node of the second pull-up transistor PU-2 are electrically connected to a power source voltage CVdd. A source node of the first pull-down transistor PD-1 and a source node of a second pull-down transistor PD-2 are electrically connected to a common voltage CVss. A source node of the second pass-gate transistor PG-2 is electrically connected to a second bit line BLB. A gate node of the first pass-gate transistor PG-1 and a gate node of the second pass-gate transistor PG-2 are electrically connected to a word line FM2_WL.

These transistors are formed by either FinFET transistor or vertically stacked multiple channels gate-all-around (GAA) horizontal nano-sheets transistor.

Referring to FIG. 4, FIG. 4 shows an equivalent circuit diagram of the SRAM cell CLi of FIG. 3. The first pull-up transistor PU-1 and the first pull-down transistor PD-1 of FIG. 1 form a first inverter INV-1. The second pull-up transistor PU-2 and the second pull-down transistor PD-2 of FIG. 1 form a second inverter INV-2. The first inverter INV-1 and the second inverter INV-2 are cross-coupled.

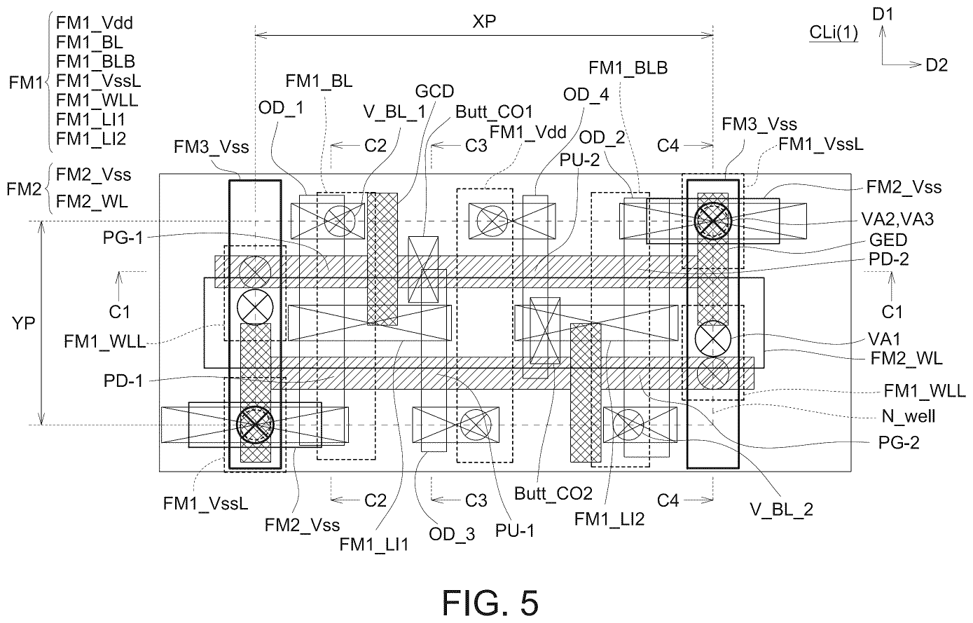

Referring to FIG. 5, FIG. 5 shows a diagrammatic plan view of an exemplified SRAM cell CLi(1) according to FIG. 1. The SRAM cell CLi(1) includes a first active region OD_1, a second active region OD_2, a third active region OD_3, a fourth active region OD_4, the first pull-up transistor PU-1, the second pull-up transistor PU-2, the first pass-gate transistor PG-1, the second pass-gate transistor PG-2, the first pull-down transistor PD-1 and the second pull-down transistor PD-2. The third active region OD_3 and the fourth active region OD_4 are located between the first active region OD_3 and the second active region OD_2.

The first active region OD_1 to the fourth active region OD_4 follow a first routing direction D1. The first pull-up transistor PU-1 is formed upon the third active region OD_3. The second pull-up transistor PU-2 is formed upon the fourth active region OD_4.

The first pass-gate transistor PG-1 is formed upon the first active region OD_1. The second pass-gate transistor PG-2 is formed upon the second active region OD_2. The first pull-down transistor PD-1 is formed upon the first active region OD_1. The second pull-down transistor PD-2 is formed upon the second active region OD_2. The first pull-up transistor PU-1 is formed upon the third active region OD_3. The second pull-up transistor PU-2 is formed upon the fourth active region OD_4.

The SRAM cell CLi(1) has a Y-pitch YP along the first routing direction D1 and a X-pitch XP along the second routing direction D2. The Y-pitch YP and the X-pitch XP are more than 1X contacted poly pitch (CPP) or 1X transistor gate pitch. For example, The X-pitch XP is 4X contacted poly pitch (CPP) or 4X transistor gate pitch. The contacted poly pitch (CPP) is the minimum distance between two parallel poly. The SRAM cell CLi(1) is rectangular shaped and the ratio of X-pitch XP and Y-pitch YP is from about 1.5 to about 3. That is, the Y-pitch YP is reduced to shrink the component size.

The SRAM cell CLi(1) includes a first level metal layer FM1, a second level metal layer FM2 and a third level metal layer FM3. The first level metal layer FM1 includes a power supply voltage conductor FM1_Vdd, a first bit-line conductor FM1_BL, a second bit-line conductor FM1_BLB, a common voltage landing pad FM1_VssL, a word-line landing line FM1_WLL, a first local connection line FM1_LI1 and a second local connection line FM1_LI2. A first contact Butt_CO1 is located under the first local connection lines FM1_LI1 and connected to the first local connection lines FM1_LI1. A second contact Butt_CO2 is located under the second local connection lines FM1_LI2 and connected to the second local connection lines FM1_LI2. The power supply voltage conductor FM1_Vdd is located in the middle of the SRAM cell CLi(1) and shared with another adjacent SRAM cell CLi(1), and electrically connected to a source node of the first pull-up transistor PU-1 and a source node of the second pull-up transistor PU-2. The common voltage landing pads FM1_VssL are located at two boundaries BD1 and BD2 of the SRAM cell CLi(1) and electrically connected to a source node of the first pull-down transistor PD-1 and a source node of the second pull-down transistor PD-2. The word-line landing lines FM1_WLL are located at two boundaries BD1 and BD2 of the SRAM cell CLi(1) and electrically connected to a gate node of the first pass-gate transistor PG-1 and a gate node of the second pass-gate transistor PG-2. The first local connection lines FM1_LI1 and the first contact Butt_CO1 are used to make an electrical connection among a drain node of the first pull-up transistor PU-1, a drain node of the first pull-down transistor PD-1, a drain node of the first pass-gate transistor PG-1, a gate node of the second pull-up transistor PU-2 and a gate node of the second pull-down transistor PD-2. The second local connection lines FM1_LI2 and the second contact Butt_CO2 are used to make an electrical connection among a drain node of the second pull-up transistor PU-2, a drain node of the second pull-down transistor PD-2, a drain node of the second pass-gate transistor PG-2, a gate node of the first pull-up transistor PU-1 and a gate node of the first pull-down transistor PD-1. The first bit-line conductor FM1_BL is electrically connected to a source node of the first pass-gate transistor PG-1, and the second bit-line conductor FM1_BLB is electrically connected to a source node of the second pass-gate transistor PG-2, such that the first pass-gate transistor PG-1 and the second pass-gate transistor PG-2 are electrically connected to individual first and second bit-line conductors FM1_BL and FM1_BLB.

The second level metal layer FM2 is located upon the first level metal layer FM1. The second level metal layer FM2 includes a word-line conductor FM2_WL and a common voltage conductor FM2_Vss. The word-line conductor FM2_WL follows a second routing direction D2 substantially perpendicular to the first routing direction D1. The common voltage conductor FM2_ Vss follows the second routing direction D2. The common voltage conductor FM2_Vss is electrically connected to the common voltage landing pad FM1_VssL through a via.

The third level metal layer FM3 is located upon the second level metal layer FM2. The third level metal layer FM3 includes two common voltage conductor lines FM3_Vss at two boundaries BD1 and BD2 of the SRAM cell CLi(1). The common voltage conductor lines FM3_Vss follow the first routing direction D1. The common voltage conductor lines FM3_Vss are electrically connected to a source node of the first pull-down transistor PD-1 and a source node of the second pull-down transistor PD-2 through the common voltage landing pad FM1_VssL and the individual common voltage conductors FM2_Vss.

In the SRAM cell CLi(1) of FIG. 5, the first bit-line conductor FM1_BL is shifted from the first active region OD_1, and the second bit-line conductor FM1_BLB is shifted from the second active region OD_2. Only part of the first bit-line conductor FM1_BL overlaps with the first active region OD_1. Only part of the second bit-line conductor FM1_BLB overlaps with the second active region OD_2. A contact V_BL_1 extends to the outside of the first active region OD_1 and does not fully cover by the first bit-line conductor FM1_BL. A contact V_BL_2 extends to the outside of the second active region OD_2 and does not fully cover by the second bit-line conductor FM1_BLB.

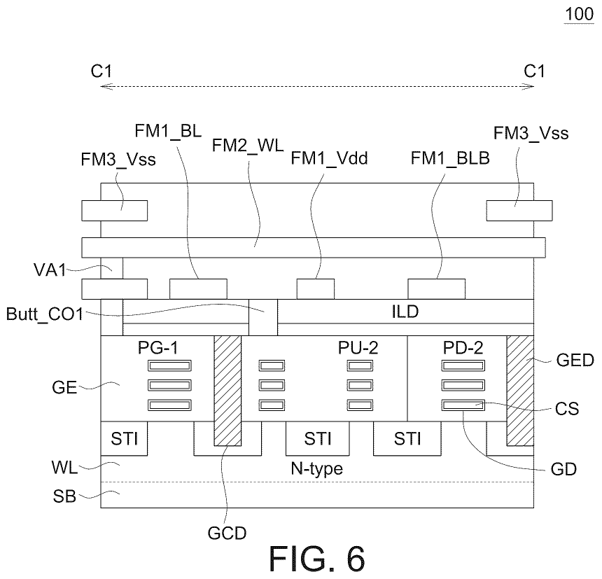

Referring to FIG. 6, FIG. 6 shows a cross section view of the semiconductor structure 100 along a cutting line C1 according to one embodiment. The first contact Butt_CO1 is formed upon a dummy dielectric gate structure DG used for isolating the second pull-up transistor PU-2 to another adjacent SRAM cell CLi(1). The second contact Butt_CO2 is formed upon a dummy dielectric gate structure (not shown) used for isolating the first pull-up transistor PU-1 to another adjacent SRAM cell CLi(1).

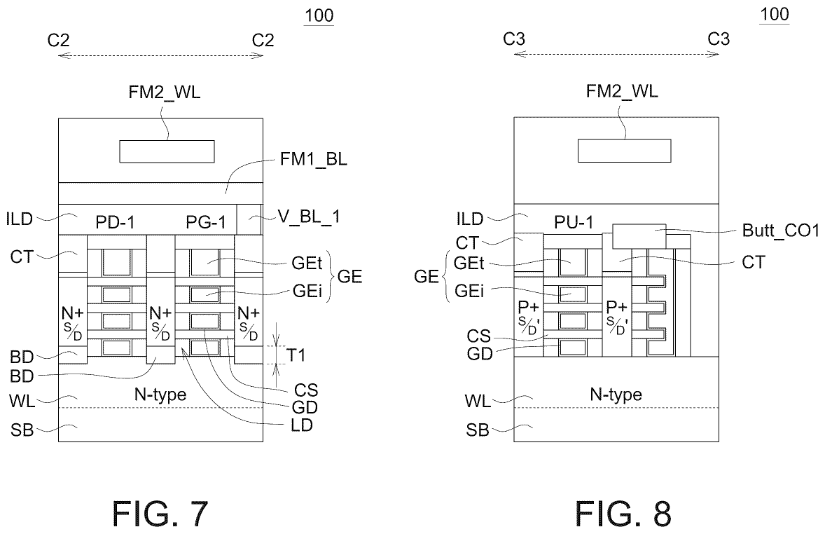

FIG. 7 shows a cross section view of the semiconductor structure 100 along a cutting line C2 according to one embodiment. FIG. 8 shows a cross section view of the semiconductor structure 100 along a cutting line C3 according to one embodiment.

As shown in the FIG. 7, a substrate SB, a N-well region WL, a plurality of channel sheets CS, a plurality of source/drain regions S/D, a plurality of contacts CT, a gate electrode GE of a pull-down transistor PD-1, a gate electrode GE of a pass-gate transistor PG-1, a plurality of gate dielectric layers GD, a plurality of spacers SP, an interlayer dielectric layer ILD, a via VA and the metal layers FM1 and FM2 of the semiconductor structure 100 are shown.

As shown in the FIG. 8, the substrate SB, the N-well region WL, the plurality of channel sheets CS, the plurality of source/drain regions S/D, the plurality of contacts CT, a gate electrode GE of a pull-down transistor PU-1, a dummy dielectric gate transistor DG, the plurality of gate dielectric layers GD, the plurality of spacers SP, the interlayer dielectric layer ILD and the metal layers FM2 of the semiconductor structure 100 are shown.

In some embodiments, the X-pitch ‘XP’ is defined from a left edge of the N-well region WL to a right edge of the N-well region WL. In some embodiments, the N-well region WL includes an N-type pass gate (PG-1) transistor and an N-type pull-down (PD-1) transistor, an N-type pass gate (PG-2) transistor and an N-type pull-down (PD-2) transistor. In some examples, the N-well region WL may include a P-type pull-up (PU-1) transistor and a P-type pull-up (PU-2) transistor. These transistors PG-1, PG-2, PD-1, PD-2, PU-1, and PU-2 are all formed upon the N-well region WL.

Each of the PG-1, PG-2, PD-1, PD-2, PU-1, and PU-2 transistors of the SRAM device 100 also include a gate structure. As shown in FIG. 6, the PG-1 transistor includes a gate electrode GE that spans perpendicularly across the channel sheets CS of the semiconductor layers. The PD-2 and PU-2 transistors include a gate electrode GE that spans perpendicularly across the channel sheets CS of the semiconductor layers. Also, similar to the PG-1, PD-2, PU-2 transistors, the PG-2 transistor includes a gate electrode GE that spans perpendicularly across the channel sheets CS of the semiconductor layers and the PD-1 and PU-1 transistors include a gate electrode that spans perpendicularly across the channel sheets CS of the semiconductor layers.

In one embodiment, as shown in the FIGS. 6 to 8, the substrate SB includes Silicon, such as a Silicon wafer. Alternatively, the substrate SB may include another elementary semiconductor, such as Germanium (Ge); a compound semiconductor, such as Silicon carbide, Gallium Arsenide (GaAs), Gallium Phosphide (GaP), Indium Phosphide (InP), Indium Arsenide (InAs), and/or Indium Antimonide (In Sb); an alloy semiconductor, such as Silicon Germanium (SiGe), GaAsP, AlInAs, AlGaAs, GaInAs, GaInP, and/or GaInAsP; or combinations thereof. Alternatively, the substrate SB is a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other suitable methods.

In one embodiment, the well region is, for example, a P-type well and is disposed in the n-type substrate. In one embodiment, as shown in the FIGS. 6 to 8, the well region WL is, for example, a N-type well and is disposed in the P-type substrate SB. In the present embodiment, the N-well region WL includes the same semiconductor material(s) as the substrate SB. The N-well region WL may be doped with n-type dopants, such as phosphorus, arsenic, other n-type dopant, or combinations thereof, configured for the PMOS and NMOS. The dopant concentration in the N-well region WL may be in a range of about 1 E16 atom/cm³ to about 1 E19 atom/cm³ in some embodiments, depending on well resistance requirements.

As shown in the FIG. 7, the source/drain regions S/D are disposed above the wells WL and electrically connected to the LDD regions LD. Each of the source/drain regions S/D includes epi profile. In the NMOS transistors, the epi material is SiP content, SiC content, SiPC, SiAs, Si, the like, or the combination thereof. The phosphorus doping concentration of source/drain regions S/D is within a range of 2 E¹⁹/cm³ to 3 E21/cm³.

As shown in the FIG. 8, the source/drain regions S/D′ are disposed above the wells WL and electrically connected to the LDD regions LD. Each of the source/drain regions S/D′ includes epi profile. In the PMOS transistor, the epi material is SiGe with Boron doped, SiGeC within Boron doped, Ge with Boron doped, Si with Boron doped, the like or the combination thereof. The Boron doping concentration of the source/drain regions S/D is within a range of 1 E19/cm³ to 6 E20/cm³.

As shown in the FIGS. 7 and 8, the source/drain regions S/D, S/D′ may be formed using epitaxial growth. For example, a semiconductor material is epitaxially grown from portions of the substrate SB, the N-well region WL, and the channel sheets CS, forming epitaxial source/drain regions S/D, S/D′. An epitaxy process can use CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of the substrate SB, the N-well region WL, and the channel sheets CS. In some embodiments, the epitaxial source/drain regions S/D may include Silicon and may be doped with Carbon, Phosphorous, Arsenic, other n-type dopant, or combinations thereof (for example, forming Si:C epitaxial source/drain regions S/D, Si:P epitaxial source/drain regions S/D, or Si:C:P epitaxial source/drain regions S/D). In some embodiments, the epitaxial source/drain regions S/D′ may include silicon germanium or germanium and may be doped with boron, other p-type dopant, or combinations thereof (for example, forming Si:Ge:B epitaxial source/drain regions S/D′). In some embodiments, the epitaxial source/drain regions S/D and/or S/D′ include more than one epitaxial semiconductor layer, where the epitaxial semiconductor layers can include the same or different materials and/or dopant concentrations. In some embodiments, the epitaxial source/drain regions S/D and/or S/D′ include materials and/or dopants that achieve desired tensile stress and/or compressive stress in respective the channel sheets CS. In some embodiments, the epitaxial source/drain regions S/D and S/D′ are doped during deposition by adding impurities to a source material of the epitaxy process (i.e., in-situ). In some embodiments, epitaxial source/drain regions S/D and S/D′ are doped by an ion implantation process subsequent to a deposition process. In some embodiments, annealing processes (e.g., rapid thermal annealing (RTA) and/or laser annealing) are performed to activate dopants in epitaxial source/drain regions S/D and S/D′. In some embodiments, epitaxial source/drain regions S/D and S/D′ are formed in separate processing sequences that include, for example, masking PMOS GAA transistor regions when forming epitaxial source/drain regions S/D in NMOS transistor and masking NMOS GAA transistor regions when forming epitaxial source/drain region S/D′ in PMOS transistor.

As shown in the FIGS. 6 to 8, the channel sheets CS are vertically stacked above the wells WL. The number of the stacked channel sheets CS is within a range of 2 to 10. For example, the number of the stacked channel sheets CS is 2, 3, or 4.

As shown in the FIGS. 7 and 8, the lightly doped source/drain (LDD) regions LD are between each of the channel sheets CS and the source/drain regions S/D, S/D′. The LDD regions LD between the channel sheets CS and the source/drain region S/D, S/D′ are surrounded by the inner spacers SPi, and the LDD regions LD between the topmost channel sheet CS and the source/drain regions S/D, S/D′ are surrounded by both of the inner spacer SPi and the top spacer SPt. The LDD regions LD provide further device performance enhance (such as short channel control) to the semiconductor structure 100.

As shown in the FIGS. 6 to 8, the vertically sheet pitch of the channel region of the vertically stacked channel sheets CS is, for example, within a range of 12 nm to 20 nm. The channel (sheet) thickness is within a range of 4 nm to 8 nm. The channel (sheet) space is within a range of 4 nm to 20 nm.

As shown in the FIGS. 6 to 8, the stack of channel sheets CS serves as the transistor channels for the respective GAA devices. The channel sheets CS may include single crystalline silicon. Alternatively, the channel sheets CS may comprise Germanium, Silicon Germanium, or another suitable semiconductor material(s). In the present embodiment, the channel sheets CS are undoped. For example, the dopant concentration in the channel sheets CS may be lower than about 1 E16 atom/cm\hat{ }3. In some embodiments, the channel sheets CS may be unintentionally doped with a very low concentration of dopants. For example, the dopant concentration in the channel sheets CS may be lower than about 5 E16 atom/cm\hat{ }3. Initially, the channel sheets CS are formed as part of a semiconductor layer stack that includes the channel sheets CS and some sacrificial semiconductor layers of a different material. During a gate replacement process, the semiconductor layer stack is selectively etched to remove the sacrificial semiconductor layers, leaving the channel sheets CS suspended over the substrate SB and between the respective source/drain regions S/D, S/D′. In various embodiments, the number of channel sheets CS in a GAA device may be in a range of 2 to 10, such as 3 or 4.

As shown in the FIGS. 7 and 8, the contacts CT are electrically connected to the source/drain regions S/D, S/D′. The gate electrodes GE surround the channel sheets CS. A material of the contacts CT comprises single metal material or multiple metal layers. The material of the contacts CT is Titanium (Ti), titanium nitride (TiN), Platinum (Pt), W (tungsten), Cobalt (Co), Ruthenium (Ru), Tungsten (W), Iridium (Ir), Rhodium (Rh), Tantalum nitride (TaN), Copper (Cu), the like, or the combination thereof.

As shown in the FIGS. 7 and 8, each of the gate electrodes GE includes at least one inner gate electrode GEi and a top gate electrode GEt. Each of the inner gate electrodes GEi is located between the channel sheets CS. Each of the top gate electrodes GEt are located upon a top of the channel sheets CS.

As shown in the FIG. 7, each of the gate electrodes GE for the NMOS transistor is disposed between a pair of N-type source/drain regions S/D. As shown in the FIG. 8, each of the gate electrodes GE for the PMOS transistor is disposed between a pair of P-type source/drain regions S/D′. In one embodiment, some gate electrodes GE straddle the PMOS transistor and the NMOS transistor, and becomes a common gate for the NMOS and the PMOS transistors.

As shown in the FIGS. 7 and 8, the gate dielectric layers GD surround the gate electrodes GE. Each of the gate dielectric layers GD includes oxide with Nitrogen doped dielectric combined with metal content high-K dielectric (K is larger than 3). The thickness of each of the gate dielectric layers GD is 0.5 nm to 3 nm. A material of the gate dielectric layers GD is Tantalum oxide, such as Ta₂O₅, Aluminum oxide, such as Al₂O₃, Hf content oxide, Titanium content oxide, Zirconium content oxide, Lanthanum content oxide, high-K material (K is equal to or larger than 9), the like or a combination thereof.

As shown in the FIGS. 7 and 8, each of the gate dielectric layers GD wrap around each of the channel sheets CS. Each of the gate dielectric layers GD may include a high-k dielectric material such as HfO₂, HfSiO, HfSiO₄, HfSiON, HfLaO, HfTaO, HTiO, HfZrO, HfAlOx, ZrO, ZrO₂, ZrSiO₂, AlO, AlSiO, Al₂O₃, TiO, TiO₂, LaO, LaSiO, Ta₂O₃, Ta₂O₅, Y₂O₃, SrTiO₃, BaZrO, BaTiO₃ (BTO), (Ba,Sr)TiO₃ (BST), Si₃N₄, hafnium dioxide-alumina (HfO₂-Al₂O₃) alloy, other suitable high-k dielectric material, or combinations thereof. High-k dielectric material generally refers to dielectric materials having a high dielectric constant, for example, greater than that of silicon oxide (k≈3.9). The gate dielectric layers GD may be formed by chemical oxidation, thermal oxidation, atomic layer deposition (ALD), chemical vapor deposition (CVD), and/or other suitable methods, and may have a thickness in a range of about 0.5 nm to about 3 nm. In some embodiments, the gate electrodes GE further include an interfacial layer between the gate dielectric layers GD and the channel sheets SC. The interfacial layer may include silicon dioxide, silicon oxynitride, or other suitable materials. In some embodiments, each of the gate electrodes GE includes an n-type work function layer for NMOS transistor, and each of the gate electrodes GE includes a p-type work function layer for PMOS transistor. For example, an n-type work function layer may comprise a metal with sufficiently low effective work function such as titanium, aluminum, tantalum carbide, tantalum carbide nitride, tantalum silicon nitride, or combinations thereof. For example, a p-type work function layer may comprise a metal with a sufficiently large effective work function, such as titanium nitride, tantalum nitride, ruthenium, molybdenum, tungsten, platinum, or combinations thereof. Since the gate electrodes GE includes a high-k dielectric layer and metal layer(s), it is also referred to as a high-k metal gate.

As shown in the FIG. 6, the gate cut dielectric layer GCD is disposed between the end of the gate electrodes GE of the pull-up transistor PU-2 and the end of the gate electrodes GE of the pass gate transistor PG-1. The gate cut dielectric layer GCD is disposed between the end of the gate electrodes GE of the pull-up transistor PU-1 and the end of the gate electrodes GE of the pass gate transistor PG-2. The gate cut dielectric layers GCD provide isolation functions for nearby transistors. In an embodiment, the gate cut dielectric layers GCD include a high-k material, such as selected from a group consisting of Si₃N₄, nitrogen-containing oxide, carbon-containing oxide, dielectric metal oxide such as HfO₂, HfSiO, HfSiO₄, HfSiON, HfLaO, HfTaO, HfTiO, HfZrO, HfAlOx, ZrO, ZrO2, ZrSiO2, AlO, AlSiO, Al2O3, TIO, TiO2, LaO, LaSiO, Ta2O3, Ta2O5, Y2O3, SrTiO3, BaZrO, BaTiO3 (BTO), (Ba,Sr)TiO3 (BST), hafnium dioxide-alumina (HfO2-Al2O3) alloy, other suitable high-k dielectric material, or combinations thereof. In one embodiment, the gate cut dielectric layers GCD has a depth that extended into STI region in a range of about 5 nm to about 60 nm.

As shown in the FIGS. 6 to 8, the interlayer dielectric layer ILD is disposed over the contacts CT, and the top gate electrodes GEt. The interlayer dielectric layer ILD may comprise tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The interlayer dielectric layer ILD may be formed by PECVD (plasma enhanced CVD), FCVD (flowable CVD), or other suitable methods.

In the embodiments described in the FIG. 7, the source/drain regions S/D are not directly connected the N-well region WL in the NMOS transistor. In the embodiments described in the FIG. 8, the source/drain regions S/D′ are directly connected the N-well region WL in the PMOS transistor. In some embodiments, an isolation layer which is a bottom dielectric layer or an un-doped silicon epi layer may be formed between the source/drain region S/D and the N-well region WL in the NMOS transistor.

As shown in the FIG. 7, the NMOS transistor of the semiconductor structure 100 includes a bottom dielectric layer BD. The bottom dielectric layer BD is located between the source/drain regions S/D and the N-well region WL in the NMOS transistor. As shown in the FIG. 8, the source/drain regions S/D′ are directly connected the wells WL in the PMOS transistor without any bottom dielectric layer.

In one embodiment, as shown in the FIG. 7, a thickness T1 of the bottom dielectric layer BD is in a range from 1 nm to 25 nm. The source/drain regions S/D with the bottom dielectric layer BD could have better isolation margin for bottom planar.

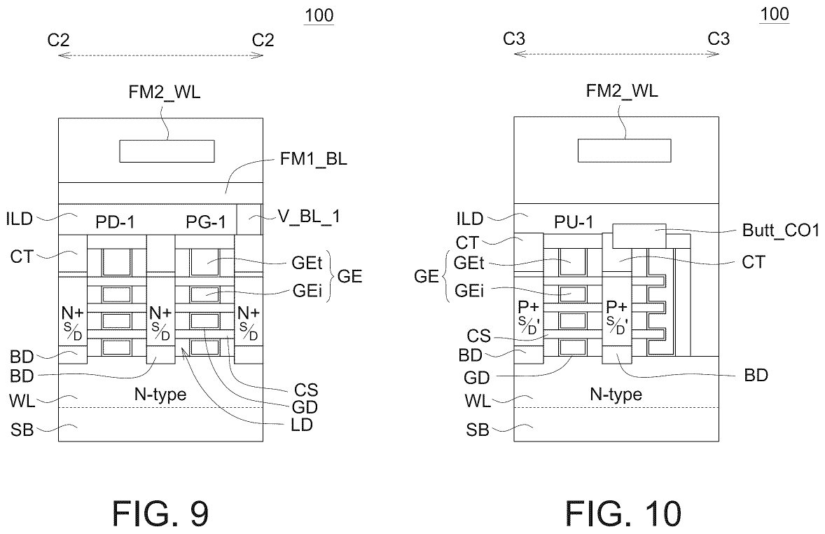

Refer to FIGS. 9 and 10. FIG. 9 shows a cross section view of a semiconductor structure 100 along the cutting line C2 (shown in the FIG. 5) according to another embodiment. FIG. 10 shows a cross section view of the semiconductor structure 100 along the cutting line C3 (shown in the FIG. 5) according to another embodiment.

As shown in the FIGS. 9 and 10, both of the NMOS transistor and the PMOS transistor of the semiconductor structure 100 include the bottom dielectric layer BD. The bottom dielectric layer BD is located between the source/drain regions S/D and the N-well region WL in the NMOS transistor and between the source/drain regions S/D′ and the N-well region WL in the PMOS transistor. The thickness T1 of the bottom dielectric layer BD is in a range from 1 nm to 25 nm. The source/drain regions S/D, S/D′ with the bottom dielectric layer BD could have better isolation margin for bottom planar.

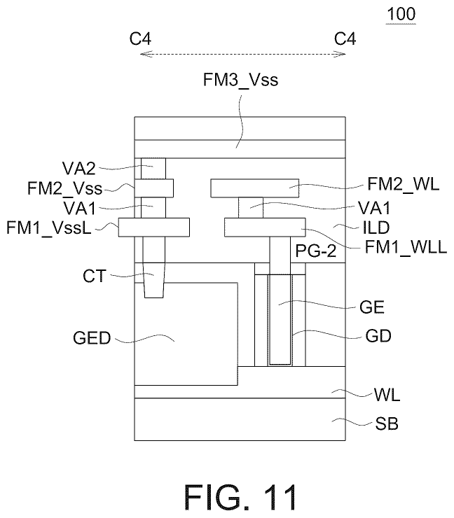

Refer to FIG. 11. FIG. 11 shows a cross section view of a semiconductor structure 100 along the cutting line C4 (shown in the FIG. 5) according to one embodiment. The gate end dielectric layers GED are disposed at ends of the gate electrodes GE so as to electrically isolate the gate electrodes GE from adjacent SRAM cell CLi(1). In some embodiments, the gate end dielectric layers GED may be formed by, for example, patterning the portion of gate structures and the ILD layer to form openings, depositing a dielectric material in the openings, and then performing a planarization process (e.g., a CMP process) to remove excess dielectric material until top surfaces of the dummy gate structures and the ILD layer are exposed. In one embodiment, the gate end dielectric layers GED has a depth that extended into STI region in a range of about 5 nm to about 60 nm.

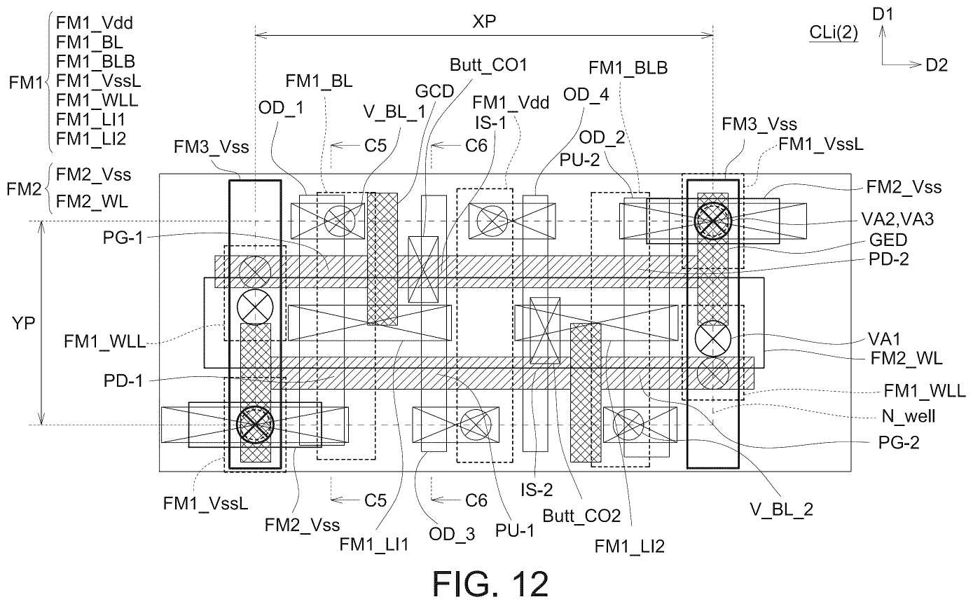

Referring to FIG. 12, FIG. 12 shows a diagrammatic plan view of an exemplified SRAM cell CLi(2) according to FIG. 3. The SRAM cell CLi(2) includes a first active region OD_1, a second active region OD_2, a third active region OD_3, a fourth active region OD_4, the first pull-up transistor PU-1, the second pull-up transistor PU-2, the first pass-gate transistor PG-1, the second pass-gate transistor PG-2, the first pull-down transistor PD-1, the second pull-down transistor PD-2, the first isolation transistor IS-1 and the second isolation transistor IS-2. The third active region OD_3 and the fourth active region OD_4 are located between the first active region OD_3 and the second active region OD_2.

The first active region OD_1 to the fourth active region OD_4 follow a first routing direction D1. The first pull-up transistor PU-1 is formed upon the third active region OD_3. The second pull-up transistor PU-2 is formed upon the fourth active region OD_4.

The first pass-gate transistor PG-1 is formed upon the first active region OD_1. The second pass-gate transistor PG-2 is formed upon the second active region OD_2. The first pull-down transistor PD-1 is formed upon the first active region OD_1. The second pull-down transistor PD-2 is formed upon the second active region OD_2. econd pass-gate transistor PG-2 is formed upon the second active region OD_2. The first pull-up transistor PU-1 and the first isolation transistor IS-1 are formed upon the third active region OD_3. The second pull-up transistor PU-2 and the second isolation transistor IS-2 are formed upon the fourth active region OD_4.

The SRAM cell CLi(2) has a Y-pitch YP along the first routing direction D1 and a X-pitch XP along the second routing direction D2. The Y-pitch YP and the X-pitch XP are more than 1X contacted poly pitch (CPP) or 1X transistor gate pitch. For example, The X-pitch XP is 4X contacted poly pitch (CPP) or 4X transistor gate pitch. The contacted poly pitch (CPP) is the minimum distance between two parallel poly. The SRAM cell CLi(2) is rectangular shaped and the ratio of X-pitch XP and Y-pitch YP is from about 1.5 to about 3. That is, the Y-pitch YP is reduced to shrink the component size.

The SRAM cell CLi(2) includes a first level metal layer FM1, a second level metal layer FM2 and a third level metal layer FM3. The first level metal layer FM1 includes a power supply voltage conductor FM1_Vdd, a first bit-line conductor FM1_BL, a second bit-line conductor FM1_BLB, a common voltage landing pad FM1_VssL, a word-line landing line FM1_WLL, first local connection lines FM1_LI1 and Butt_CO1 and second local connection lines FM1_LI2 and Butt_CO2. The power supply voltage conductor FM1_Vdd is located in the middle of the SRAM cell CLi(2) and shared with another adjacent SRAM cell CLi(2), and electrically connected to a source node of the first pull-up transistor PU-1 and a source node of the second pull-up transistor PU-2. The common voltage landing pad FM1_VssL is electrically connected to a source node of the first pull-down transistor PD-1 and a source node of the second pull-down transistor PD-2. The word-line landing lines FM1_WLL are located at two boundaries BD1 and BD2 of the SRAM cell CLi (2) and electrically connected to a gate node of the first pass-gate transistor PG-1 and a gate node of the second pass-gate transistor PG-2. The first local connection lines FM1_LI1 and Butt_CO1 are used to make an electrical connection among a drain node of the first pull-up transistor PU-1, a drain node of the first pull-down transistor PD-1, a drain node of the first pass-gate transistor PG-1, a drain of the first isolation transistor IS-1, a gate node of the second pull-up transistor PU-2 and a gate node of the second pull-down transistor PD-2. The second local connection lines FM1_LI2 and Butt_CO2 are used to make an electrical connection among a drain node of the second pull-up transistor PU-2, a drain node of the second pull-down transistor PD-2, a drain node of the second pass-gate transistor PG-2, a drain node of the second isolation transistor IS-2, a gate node of the first pull-up transistor PU-1 and a gate node of the first pull-down transistor PD-1. The first bit-line conductor FM1_BL is electrically connected to a source node of the first pass-gate transistor PG-1, and the second bit-line conductor FM1_BLB is electrically connected to a source node of the second pass-gate transistor PG-2.

The second level metal layer FM2 is located upon the first level metal layer FM1. The second level metal layer FM2 includes a word-line conductor FM2_WL and a common voltage conductor FM2_Vss. The word-line conductor FM2_WL follows a second routing direction D2 substantially perpendicular to the first routing direction D1. The common voltage conductor FM2_Vss follows the second routing direction D2. The common voltage conductor FM2_Vss is electrically connected to the common voltage landing pad FM1_VssL through a via.

The third level metal layer FM3 is located upon the second level metal layer FM2. The third level metal layer FM3 includes two common voltage conductors FM3_Vss at two boundaries BD1 and BD2 of the SRAM cell CLi(2). The common voltage conductors FM3_Vss follow the first routing direction D1. The common voltage conductors FM3_Vss are electrically connected to a source node of the first pull-down transistor PD-1 and a source node of the second pull-down transistor PD-2 through the common voltage landing pad FM1_VssL and the common voltage conductors FM2_ Vss.

In the SRAM cell CLi (2) of FIG. 12, the first bit-line conductor FM1_BL is shifted from the first active region OD_1, and the second bit-line conductor FM1_BLB is shifted from the second active region OD_2. Only part of the first bit-line conductor FM1_BL overlaps with the first active region OD_1. Only part of the second bit-line conductor FM1_BLB overlaps with the second active region OD_2. A contact V_BL_1 extends to the outside of the first active region OD_1 and does not fully cover by the first bit-line conductor FM1_BL. A contact V_BL_2 extends to the outside of the second active region OD_2 and does not fully cover by the second bit-line conductor FM1_BLB.

In the SRAM cell CLi(2) of FIG. 12, the source node of the first isolation transistor IS-1 is electrically floated. That is, the source node of the first isolation transistor IS-1 is not electrically connected to a power source voltage CVdd through the power supply voltage conductor FM1_Vdd. In addition, the source node of the second isolation transistor IS-2 is electrically floated and shared with adjacent SRAM cell's floating source node. That is, the source node of the second isolation transistor IS-2 is not electrically connected to a power source voltage CVdd through the power supply voltage conductor FM1_Vdd.

In the SRAM cell CLi(2) of FIG. 12, the first isolation transistor IS-1 is located adjacent to the second pull-up transistor PU-2 and breaks the third active region OD_3. The first isolation transistor IS-1 has a common drain and gate connection and a floating source node. The common drain and gate connection is electrically connected to a drain node of the first pull-up transistor and the floating source node is shared with the floating source node of adjacent SRAM cell CLi(2).

The second isolation transistor IS-2 is located adjacent to the first pull-up transistor PU-1 and breaks the fourth active region OD_4. The second isolation transistor IS-2 has a common drain and gate connection and a floating source node. The common drain and gate connection is electrically connected to a drain node of the second pull-up transistor and the floating source node is shared with the floating source node of adjacent SRAM cell CLi(2).

The first contact Butt_CO1 is formed upon the first isolation transistor IS-1, and the first isolation transistor IS-1 may be a dummy gate structure DG (see FIG. 6) used for isolating the gate node of second pull-up transistor PU-2 from another adjacent SRAM cell CLi(2). The second contact Butt_CO2 is formed upon the second isolation transistor IS-2, and the second isolation transistor IS-2 may be a dummy gate structure (not shown) used for isolating the first pull-up transistor PU-1 from another adjacent SRAM cell CLi(2).

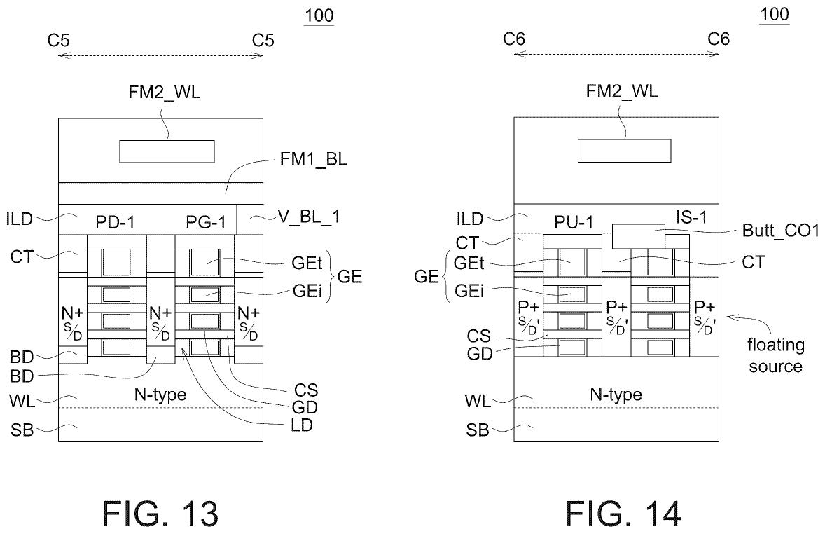

FIG. 13 shows a cross section view of the semiconductor structure 100 along a cutting line C5 (shown in the FIG. 12) according to one embodiment. FIG. 14 shows a cross section view of the semiconductor structure 100 along a cutting line C6 (shown in the FIG. 12) according to one embodiment.

In the embodiments described in the FIG. 13, the source/drain regions S/D are not directly connected the N-well region WL in the NMOS transistor (i.e., PD-1 and PG-1 transistors). In the embodiments described in the FIG. 14, the source/drain regions S/D′ are directly connected the N-well region WL in the PMOS transistor (i.e., PU-1 transistors). In some embodiments, an isolation layer which is a bottom dielectric layer or an un-doped silicon epi layer may be formed between the source/drain region S/D and the N-well region WL in the NMOS transistor (i.e., PD-1 and PG-1 transistors).

As shown in the FIG. 13, the NMOS transistor of the semiconductor structure 100 includes a bottom dielectric layer BD. The bottom dielectric layer BD is located between the source/drain regions S/D and the N-well region WL in the NMOS transistor. As shown in the FIG. 14, the source/drain regions S/D′ are directly connected the N-well region WL in the PMOS transistor without any bottom dielectric layer.

In one embodiment, as shown in the FIG. 13, a thickness T1 of the bottom dielectric layer BD is in a range from 1 nm to 25 nm. The source/drain regions S/D with the bottom dielectric layer BD could have better isolation margin for bottom planar.

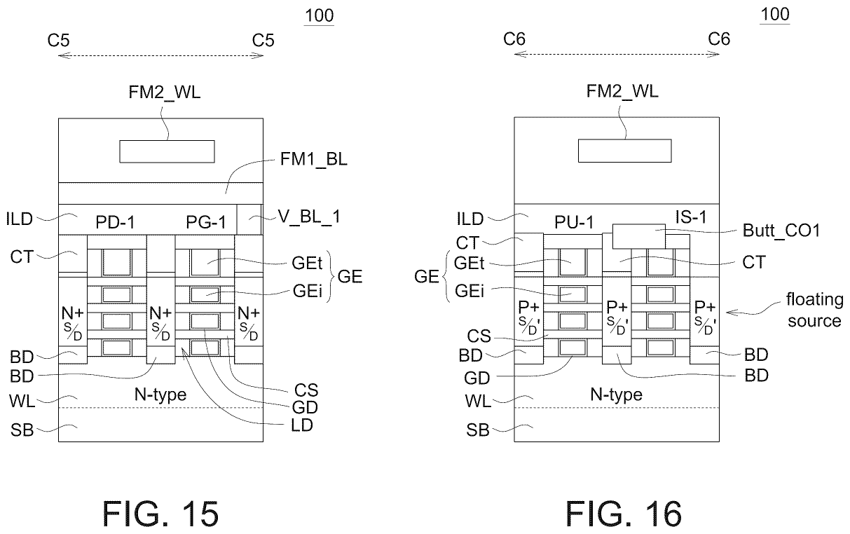

Refer to FIGS. 15 and 16. FIG. 15 shows a cross section view of a semiconductor structure 100 along the cutting line C5 (shown in the FIG. 12) according to another embodiment. FIG. 16 shows a cross section view of the semiconductor structure 100 along the cutting line C6 (shown in the FIG. 12) according to another embodiment.

As shown in the FIGS. 15 and 16, both of the NMOS transistor and the PMOS transistor of the semiconductor structure 100 include the bottom dielectric layer BD. The bottom dielectric layer BD is located between the source/drain regions S/D and the N-well region WL in the NMOS transistor (i.e., PD-1 and PG-1 transistors) and between the source/drain regions S/D′ and the N-well region WL in the PMOS transistor (i.e., PU-1 transistor). The thickness T1 of the bottom dielectric layer BD is in a range from 1 nm to 25 nm. The source/drain regions S/D, S/D′ with the bottom dielectric layer BD could have better isolation margin for bottom planar.

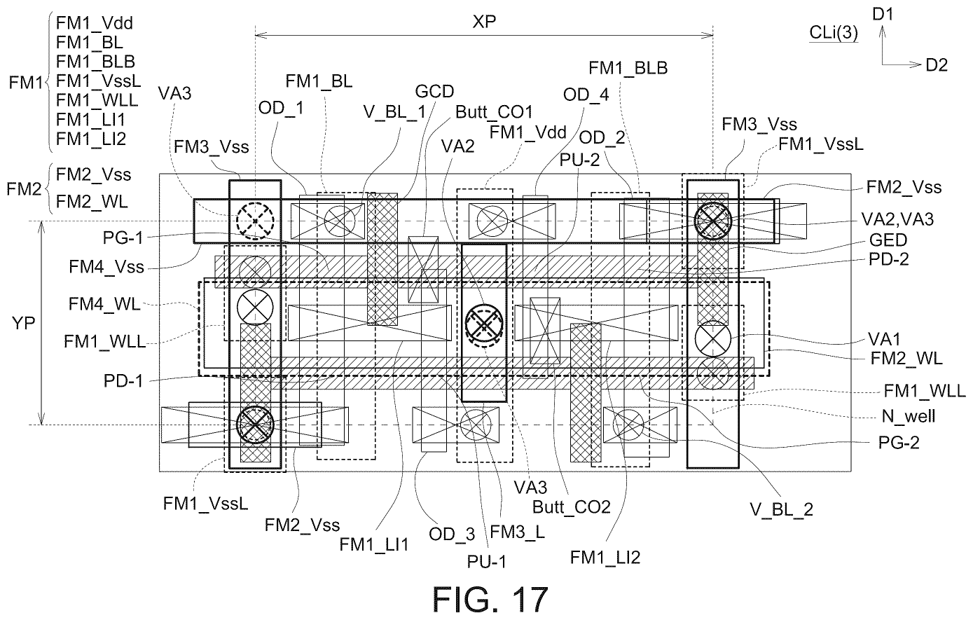

Referring to FIG. 17, FIG. 17 shows another diagrammatic plan view of an exemplified SRAM cell CLi(3) according to FIG. 1. The SRAM cell CLi(3) includes a first active region OD_1, a second active region OD_2, a third active region OD_3, a fourth active region OD_4, the first pull-up transistor PU-1, the second pull-up transistor PU-2, the first pass-gate transistor PG-1, the second pass-gate transistor PG-2, the first pull-down transistor PD-1 and the second pull-down transistor PD-2. The third active region OD_3 and the fourth active region OD_4 are located between the first active region OD_3 and the second active region OD_2.

The first active region OD_1 to the fourth active region OD_4 follow a first routing direction D1. The first pass-gate transistor PG-1 is formed upon the first active region OD_1. The second pass-gate transistor PG-2 is formed upon the second active region OD_2. The first pull-down transistor PD-1 is formed upon the first active region OD_1. The second pull-down transistor PD-2 is formed upon the second active region OD_2. The first pull-up transistor PU-1 is formed upon the third active region OD_3. The second pull-up transistor PU-2 is formed upon the fourth active region OD_4.

The SRAM cell CLi(3) has a Y-pitch YP along the first routing direction D1 and a X-pitch XP along the second routing direction D2. The Y-pitch YP and the X-pitch XP are more than 1X contacted poly pitch (CPP) or 1X transistor gate pitch. For example, The X-pitch XP is 4X contacted poly pitch (CPP) or 4X transistor gate pitch. The contacted poly pitch (CPP) is the minimum distance between two parallel poly. The SRAM cell CLi(3) is rectangular shaped and the ratio of X-pitch XP and Y-pitch YP is from about 1.5 to about 3. That is, the Y-pitch YP is reduced to shrink the component size.

The SRAM cell CLi(3) includes a first level metal layer FM1, a second level metal layer FM2, a third level metal layer FM3 and a fourth level metal layer FM4. The first level metal layer FM1 includes a power supply voltage conductor FM1_Vdd, a first bit-line conductor FM1_BL, a second bit-line conductor FM1_BLB, a common voltage landing pad FM1_VssL, a word-line landing line FM1_WLL, a first local connection lines FM1_LI1, a second local connection line FM1_LI2. A first contact Butt_CO1 is located under the first local connection lines FM1_LI1 and connected to the first local connection lines FM1_LI1. A second contact Butt_CO2 is located under the second local connection lines FM1_LI2 and connected to the second local connection lines FM1_LI2. The power supply voltage conductor FM1_ Vdd is located in the middle of the SRAM cell CLi(3) and shared with another adjacent SRAM cell CLi(3), and electrically connected to a source node of the first pull-up transistor PU-1 and a source node of the second pull-up transistor PU-2. The common voltage landing pad FM1_VssL is electrically connected to a source node of the first pull-down transistor PD-1 and a source node of the second pull-down transistor PD-2. The word-line landing lines FM1_WLL are located at two boundaries BD1 and BD2 of the SRAM cell CLi(1) and electrically connected to a gate node of the first pass-gate transistor PG-1 and a gate node of the second pass-gate transistor PG-2. The first local connection lines FM1_LI1 and the first contact Butt_CO1 are used to make an electrical connection among a drain node of the first pull-up transistor PU-1, a drain node of the first pull-down transistor PD-1, a drain node of the first pass-gate transistor PG-1, a gate node of the second pull-up transistor PU-2 and a gate node of the second pull-down transistor PD-2. The second local connection lines FM1_LI2 and the second contact Butt_CO2 are used to make an electrical connection among a drain node of the second pull-up transistor PU-2, a drain node of the second pull-down transistor PD-2, a drain node of the second pass-gate transistor PG-2, a gate node of the first pull-up transistor PU-1 and a gate node of the first pull-down transistor PD-1. The first bit-line conductor FM1_BL is electrically connected to a source node of the first pass-gate transistor PG-1, and the second bit-line conductor FM1_BLB is electrically connected to a source node of the second pass-gate transistor PG-2, such that the first pass-gate transistor PG-1 and the second pass-gate transistor PG-2 are electrically connected to individual first and second bit-line conductors FM1_BL and FM1_BLB.

The second level metal layer FM2 is located upon the first level metal layer FM1. The second level metal layer FM2 includes a first word-line conductor FM2_WL and a first common voltage conductor FM2_Vss. The first word-line conductor FM2_ WL follows a second routing direction D2 substantially perpendicular to the first routing direction D1. The first common voltage conductor FM2_ Vss follows the second routing direction D2. The common voltage conductor FM2_Vss is electrically connected to the common voltage landing pad FM1_VssL through a via VA1.

The third level metal layer FM3 is located upon the second level metal layer FM2. The third level metal layer FM3 includes two common voltage conductor lines FM3_Vss at two boundaries BD1 and BD2 of the SRAM cell CLi(3). The common voltage conductor lines FM3_Vss follow the first routing direction D1. The common voltage conductor lines FM3_Vss are electrically connected to a source node of the first pull-down transistor PD-1 and a source node of the second pull-down transistor PD-2 through the common voltage landing pad FM1_VssL and the individual common voltage conductors FM2_Vss.

In the SRAM cell CLi(3) of FIG. 17, the first bit-line conductor FM1_BL is shifted from the first active region OD_1, and the second bit-line conductor FM1_BLB is shifted from the second active region OD_2. Only part of the first bit-line conductor FM1_BL overlaps with the first active region OD_1. Only part of the second bit-line conductor FM1_BLB overlaps with the second active region OD_2. A contact V_BL_1 extends to the outside of the first active region OD_1 and does not fully cover by the first bit-line conductor FM1_BL. A contact V_BL_2 extends to the outside of the second active region OD_2 and does not fully cover by the second bit-line conductor FM1_BLB.

The fourth level metal layer FM4 is located upon the third level metal layer FM3. The fourth level metal layer FM4 includes a second word-line conductor FM4_WL and a second common voltage conductor FM4_Vss. The second word-line conductor FM4_WL follows a second routing direction D2 substantially perpendicular to the first routing direction D1. The second common voltage conductor FM4_Vss follows the second routing direction D2. The second common voltage conductors FM4_Vss is electrically connected to the two common voltage conductor lines FM3_Vss located at the two boundary BD1 and BD2 respectively.

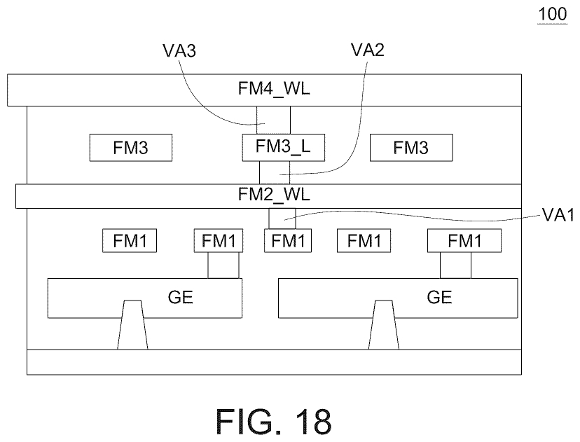

Referring to FIG. 18, FIG. 18 shows an arrangement of four level metal layers FM1 to FM4 stacked in the integrated circuit structure 100. The second word-line conductor FM4_WL is located upon the third level metal layer FM3. The second word-line conductor FM4_WL and the first word-line conductor FM2_WL are electrically connected through two vias VA2, VA3 and a landing pad FM3_L of the third level metal layer FM3.

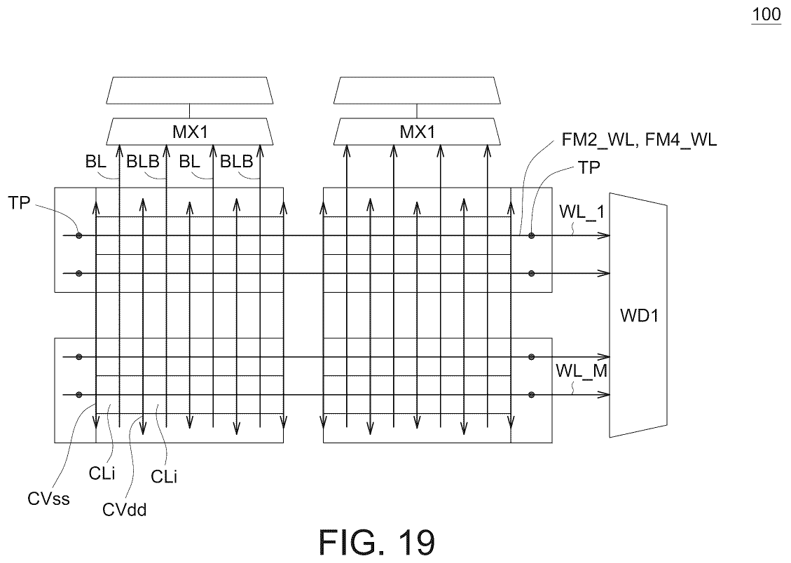

Referring to FIG. 19, FIG. 19 shows an arrangement of the SRAM cells CLi in the integrated circuit structure 100. The SRAM cells CLi are arranged in an array. A plurality of first bit lines BL connected to the first bit-line conductor FM1_BL and a plurality of second bit lines BLB connected to the second bit-line conductor FM1_BLB of the SRAM cells CLi are connected to a column MUX MX1. Each of a plurality of word lines WL_1 to WL_M connected to the first word-line conductor FM2_WL and the second word-line conductor FM4_WL of the SRAM cell CLi is connected to the word line decoder WD1.

As shown in FIG. 19, the integrated circuit structure 100 further includes at least one edge tap structure TP. The edge tap structures TP are located at an edge of the array of the SRAM cells CLi. Each of the edge tap structures TP is used to make an electrical connection among the second level metal layer FM2 and the fourth level metal layer FM4 of the SRAM cells CLi, such that the first word-line conductor FM2_WL and the second word-line conductor FM4_WL of the SRAM cells CLi could be connected to the word lines WL_1 to WL_M on the same row.

The present disclosure is directed to an integrated circuit structure, which includes at least one SRAM cell. Each of the at least one SRAM cell is formed on a N-well region of a P-type substrate. In some embodiments, the first pass-gate transistor, the second pass-gate transistor, the first pull-down transistor and the second pull-down transistor are NMOS transistors having a bottom dielectric layer disposed on the N-well region of the P-type substrate, and the first pull-up transistor and the second pull-up transistor are PMOS transistors without the bottom dielectric layer. The source/drain regions of NMOS transistors with the bottom dielectric layer could have better Iboff and Isoff reduction and better capacitance reduction. The epi-growth regions of PMOS transistors directly formed on the bottom silicon coulud have better Ion performance.

According to some embodiments of the present disclosure, an integrated circuit structure is provided. The integrated circuit structure includes at least one static random-access memory (SRAM) cell. The SRAM cell includes a first active region, a second active region, a third active region, a fourth active region, a first pull-up transistor, a second pull-up transistor, a first pass-gate transistor, a second pass-gate transistor, a first pull-down transistor and a second pull-down transistor. The first active region to the fourth active region follow a first routing direction. The first pull-up transistor is formed upon the third active region. The second pull-up transistor is formed upon the third active region. The first pass-gate transistor and the first pull-down transistor are formed upon the first active region. The second pass-gate transistor and the second pull-down transistor are formed upon the second active region. Each of the at least one SRAM cell is formed on a N-well region of a P-type substrate.

According to some embodiments of the present disclosure, an integrated circuit structure is provided. The integrated circuit structure includes at least one static random- access memory (SRAM) cell. The SRAM cell includes a first active region, a second active region, a third active region, a fourth active region, a first pull-up transistor, a second pull-up transistor, a first pass-gate transistor, a second pass-gate transistor, a first pull-down transistor, a second pull-down transistor, a first isolation transistor and a second isolation transistor. The first active region to the fourth active region follow a first routing direction. The first pull-up transistor is formed upon the third active region. The second pull-up transistor is formed upon the third active region. The first pass-gate transistor and the first pull-down transistor are formed upon the first active region. The second pass-gate transistor and the second pull-down transistor are formed upon the second active region. The first isolation transistor is located adjacent to the second pull-up transistor and breaks the third active region, the first isolation transistor has a common drain and gate connection and a floating source node. The second isolation transistor is located adjacent to the first pull-up transistor and breaks the fourth active region, the second isolation transistor has another common drain and gate connection and another floating source node. The common drain and gate connection is electrically connected to a drain node of the first pull-up transistor, and the another common drain and gate connection is electrically connected to a drain node of the second pull-up transistor.

According to some embodiments of the present disclosure, an integrated circuit structure is provided. The integrated circuit structure includes at least one static random-access memory (SRAM) cell. The SRAM cell includes a first active region, a second active region, a third active region, a fourth active region, a first pull-up transistor, a second pull-up transistor, a first pass-gate transistor, a second pass-gate transistor, a first pull-down transistor, a second pull-down transistor, a first isolation transistor and a second isolation transistor. The first active region to the fourth active region follow a first routing direction. The first pull-up transistor is formed upon the third active region. The second pull-up transistor is formed upon the third active region. The first pass-gate transistor and the first pull-down transistor are formed upon the first active region. The second pass-gate transistor and the second pull-down transistor are formed upon the second active region. The first isolation transistor is located adjacent to the second pull-up transistor and breaks the third active region, the first isolation transistor has a common drain and gate connection and a floating source node. The second isolation transistor is located adjacent to the first pull-up transistor and breaks the fourth active region, the second isolation transistor has another common drain and gate connection and another floating source node. The first pass-gate transistor, the second pass-gate transistor, the first pull-down transistor and the second pull-down transistor are NMOS transistors having a bottom dielectric layer disposed on a N-well region of a P-type substrate, and the first pull-up transistor and the second pull-up transistor are PMOS transistors without the bottom dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit structure, comprising:
at least one static random-access memory (SRAM) cell, including:
a first active region, following a first routing direction;
a second active region, following the first routing direction;
a third active region, following the first routing direction;
a fourth active region, following the first routing direction;
a first pull-up transistor, formed upon the third active region;
a second pull-up transistor, formed upon the fourth active region;
a first pass-gate transistor, formed upon the first active region;
a second pass-gate transistor, formed upon the second active region;
a first pull-down transistor, formed upon the first active region; and
a second pull-down transistor, formed upon the second active region;
wherein each of the at least one SRAM cell is formed on a N-well region of a P-type substrate.

2. The integrated circuit structure according to claim 1, wherein each of the at least one SRAM cell comprises:
a first level metal layer, including:
a first power supply voltage conductor, located in a middle of the SRAM cell and shared with another adjacent SRAM cell, and electrically connected to a source node of the first pull-up transistor and a source node of the second pull-up transistor;
a common voltage landing pad, located at two boundaries of the SRAM cell, electrically connected to a source node of the first pull-down transistor and a source node of the second pull-down transistor;
a word-line landing line, located at the two boundaries of the SRAM cell, and electrically connected to a gate node of the first pass-gate transistor and a gate node of the second pass-gate transistor;
a first local connection line and a first contact, used to make an electrical connection among a drain node of the first pull-up transistor, a drain node of the first pull-down transistor, a drain node of the first pass-gate transistor, a gate node of the second pull-up transistor and a gate node of the second pull-down transistor; and
a second local connection line and a second contact, used to make an electrical connection among a drain node of the second pull-up transistor, a drain node of the second pull-down transistor, a drain node of the second pass-gate transistor, a gate node of the first pull-up transistor and a gate node of the first pull-down transistor;
a first bit-line conductor electrically connected to the source node of the first pass-gate transistor; and
a second bit-line conductor electrically connected to the source node of the second pass-gate transistor;
a second level metal layer, located upon the first level metal layer, including:
a first word-line conductor, following a second routing direction substantially perpendicular to the first routing direction; and
a common voltage conductor, following the second routing direction and electrically connected to the common voltage landing pad; and
a third level metal layer, located upon the second level metal layer, including:
two common voltage conductor lines, following the first routing direction, and electrically connected to the source node of the first pull-down transistor and the source node of the second pull-down transistor.

3. The integrated circuit structure according to claim 2, wherein the first contact is electrically connected to the drain node of the first pull-down transistor and the gate node of the second pull-up transistor, and the second contact is electrically connected to the drain node of the second pull-down transistor and the gate node of the first pull-up transistor.

4. The integrated circuit structure according to claim 3, wherein each of the at least one SRAM cell further comprises:
a first isolation transistor, located adjacent to the second pull-up transistor and breaks the third active region, the first isolation transistor having a common drain and gate connection and a floating source node; and
a second isolation transistor, located adjacent to the first pull-up transistor and breaks the fourth active region, the second isolation transistor having another common drain and gate connection and another floating source node.

5. The integrated circuit structure according to claim 4, wherein the first contact is formed upon the first isolation transistor, and the first isolation transistor is a dummy gate structure.

6. The integrated circuit structure according to claim 4, wherein the second contact is formed upon the second isolation transistor, and the second isolation transistor is a dummy gate structure.

7. The integrated circuit structure according to claim 2, wherein each of the at least one SRAM cell further includes:
a fourth level metal layer, located upon the third level metal layer, including:
a second word-line conductor, following the second routing direction and electrically connected to the first word-line conductor; and
a second common voltage conductor, following the second routing direction, and electrically connected to the two common voltage conductor lines.

8. The integrated circuit structure according to claim 7, further comprising:
at least one edge tap structure, located at an edge of an array of the at least one SRAM cell and used to make an electrical connection among the first word-line conductor and the second word-line conductor.

9. The integrated circuit structure according to claim 1, wherein the first pass-gate transistor, the second pass-gate transistor, the first pull-down transistor and the second pull-down transistor are NMOS transistors having a bottom dielectric layer disposed on the N-well region, and the first pull-up transistor and the second pull-up transistor are PMOS transistors without the bottom dielectric layer.

10. The integrated circuit structure according to claim 1, wherein the first pass-gate transistor, the second pass-gate transistor, the first pull-down transistor and the second pull-down transistor are NMOS transistors having a bottom dielectric layer disposed on the N-well region, and the first pull-up transistor and the second pull-up transistor are PMOS transistors having the bottom dielectric layer disposed on the N-well region.

11. An integrated circuit structure, comprising:
at least one static random-access memory (SRAM) cell, including:
a first active region, following a first routing direction;
a second active region, following the first routing direction;
a third active region, following the first routing direction;
a fourth active region, following the first routing direction;
a first pull-up transistor, formed upon the third active region;
a second pull-up transistor, formed upon the fourth active region;
a first pass-gate transistor, formed upon the first active region;
a second pass-gate transistor, formed upon the second active region;
a first pull-down transistor, formed upon the first active region;
a second pull-down transistor, formed upon the second active region;
a first isolation transistor, located adjacent to the second pull-up transistor and breaks the third active region, the first isolation transistor having a common drain and gate connection and a floating source node; and
a second isolation transistor, located adjacent to the first pull-up transistor and breaks the fourth active region, the second isolation transistor having another common drain and gate connection and another floating source node,
wherein the common drain and gate connection is electrically connected to a drain node of the first pull-up transistor, and the another common drain and gate connection is electrically connected to a drain node of the second pull-up transistor.

12. The integrated circuit structure according to claim 11, wherein each of the at least one SRAM cell comprises:
a first level metal layer, including:
a first power supply voltage conductor, located in a middle of the SRAM cell and shared with another adjacent SRAM cell, and electrically connected to a source node of the first pull-up transistor and a source node of the second pull-up transistor;
a common voltage landing pad, located at two boundaries of the SRAM cell, electrically connected to a source node of the first pull-down transistor and a source node of the second pull-down transistor;
a word-line landing line, located at the two boundaries of the SRAM cell, and electrically connected to a gate node of the first pass-gate transistor and a gate node of the second pass-gate transistor;
a first local connection line and a first contact, used to make an electrical connection among a drain node of the first pull-up transistor, a drain node of the first pull-down transistor, a drain node of the first pass-gate transistor, a gate node of the second pull-up transistor and a gate node of the second pull-down transistor; and
a second local connection line and a second contact, used to make an electrical connection among a drain node of the second pull-up transistor, a drain node of the second pull-down transistor, a drain node of the second pass-gate transistor, a gate node of the first pull-up transistor and a gate node of the first pull-down transistor;
a first bit-line conductor electrically connected to the source node of the first pass-gate transistor; and
a second bit-line conductor electrically connected to the source node of the second pass-gate transistor;
a second level metal layer, located upon the first level metal layer, including:
a first word-line conductor, following a second routing direction substantially perpendicular to the first routing direction; and
a common voltage conductor, following the second routing direction and electrically connected to the common voltage landing pad; and
a third level metal layer, located upon the second level metal layer, including:
two common voltage conductor lines, following the first routing direction, and electrically connected to the source node of the first pull-down transistor and the source node of the second pull-down transistor.

13. The integrated circuit structure according to claim 12, wherein the first contact is electrically connected to the drain node of the first pull-down transistor and the gate node of the second pull-up transistor, and the second contact is electrically connected to the drain node of the second pull-down transistor and the gate node of the first pull-up transistor.

14. The integrated circuit structure according to claim 12, wherein the first contact is formed upon the first isolation transistor, and the first isolation transistor is a dummy gate structure.

15. The integrated circuit structure according to claim 12, wherein the second contact is formed upon the second isolation transistor, and the second isolation transistor is a dummy gate structure.

16. The integrated circuit structure according to claim 12, wherein each of the at least one SRAM cell further includes:
a fourth level metal layer, located upon the third level metal layer, including:
a second word-line conductor, following the second routing direction and electrically connected to the first word-line conductor; and
a second common voltage conductor, following the second routing direction, and electrically connected to the two common voltage conductor lines.

17. The integrated circuit structure according to claim 16, further comprising:
at least one edge tap structure, located at an edge of an array of the at least one SRAM cell and used to make an electrical connection among the first word-line conductor and the second word-line conductor.

18. The integrated circuit structure according to claim 11, wherein the first pass-gate transistor, the second pass-gate transistor, the first pull-down transistor and the second pull-down transistor are NMOS transistors having a bottom dielectric layer disposed on a N-well region of a P-type substrate, and the first pull-up transistor and the second pull-up transistor are PMOS transistors without the bottom dielectric layer.

19. The integrated circuit structure according to claim 11, wherein the first pass-gate transistor, the second pass-gate transistor, the first pull-down transistor and the second pull-down transistor are NMOS transistors having a bottom dielectric layer disposed on a N-well region of a P-type substrate, and the first pull-up transistor and the second pull-up transistor are PMOS transistors having the bottom dielectric layer disposed on the N-well region.

20. An integrated circuit structure, comprising:
at least one static random-access memory (SRAM) cell, including:
a first active region, following a first routing direction;
a second active region, following the first routing direction;
a third active region, following the first routing direction;
a fourth active region, following the first routing direction;
a first pull-up transistor, formed upon the third active region;
a second pull-up transistor, formed upon the fourth active region;
a first pass-gate transistor, formed upon the first active region;
a second pass-gate transistor, formed upon the second active region;
a first pull-down transistor, formed upon the first active region;
a second pull-down transistor, formed upon the second active region;
a first isolation transistor, located adjacent to the second pull-up transistor and breaks the third active region, the first isolation transistor having a common drain and gate connection and a floating source node; and
a second isolation transistor, located adjacent to the first pull-up transistor and breaks the fourth active region, the second isolation transistor having another common drain and gate connection and another floating source node,
wherein the first pass-gate transistor, the second pass-gate transistor, the first pull-down transistor and the second pull-down transistor are NMOS transistors having a bottom dielectric layer disposed on a N-well region of a P-type substrate, and the first pull-up transistor and the second pull-up transistor are PMOS transistors without the bottom dielectric layer.
